(19) United States
(12) Patent Application Publication
(10) Pub. No.: US 2007/0108526 A1
(43) Pub. Date: May 17, 2007

(54) Strained silicon CMOS devices

(75) Inventor: Yusuke Kohyama, Kanagawa (JP)

Correspondence Address: BANNER & WITCOFF, LTD., 1100 13th STREET, N.W., SUITE 1200, WASHINGTON, DC, 20005-4051, US

(73) Assignee: Toshiba America Electronic Components, Inc., Irvine, CA (US)

(21) Appl. No.: 11/271,910

(22) Filed: Nov. 14, 2005

(51) Int. Cl. H01L 27/12

(52) U.S. Cl. 257/351

(57) ABSTRACT

Improved ways of controlling the boundaries between the compressive and tensile portions of a dual-stress liner in a semiconductor device are described. The boundaries may be appropriately designed to be located by a predetermined distance as measured from a PFET feature, such as the channel or the active area boundary, as opposed to being dictated by the N-well boundaries. This may provide the opportunity to improve and/or match PFET performance. By appropriately designing the boundaries between the compressive and tensile portions of the dual-stress liner, the compressive stress on a PFET may be reduced in the y direction while maintained or even increased in the x direction, potentially resulting in improved PFET performance.

### BACKGROUND

Strained silicon technologies such as silicon-germanium-on-insulator (SGOI), embedded silicon-germanium (SiGe), and silicon nitride (SiN) stress liners, have recently received significant attention for their abilities to enhance mobility in silicon devices. N-channel field-effect transistors (NFETs) have the property that tensile stress applied to their channels in the x and/or y directions enhances NFET mobility. For a given FET, the x direction as referred to in the present disclosure and claims is defined as the direction parallel to the current flow between the source and drain of the FET, and the y direction as referred to in the present disclosure and claims is defined as the direction perpendicular to the x direction and along the FET channel width. P-channel field-effect transistors (PFETs) have the property that tensile stress applied to their channels in the y direction enhances PFET mobility, and compressive stress applied to their channels in the x direction enhances PFET mobility. To take advantage of these properties, dual-stress liner technology has been developed to provide tensile stress to NFETs and compressive stress to PFETs. Some performance improvements have been achieved using such dual-stress liners. However, performance improvements so far have been limited due to the inability of conventional dual-stress liners to apply consistent and appropriate stress to groups of PFETs and NFETs.

For example, referring to FIG. 1, in general, a PFET 101 and an NFET 100 each have an active area 1, 102, a gate 3, 103, and a pair of contacts 4, 104 on opposing sides of respective gates 3, 103. An N-well 2 covers PFET 101, and the portion not covered by N-well 2 is considered a P-well 105. Although FIG. 1 is not drawn to scale, in this particular device, active area 1 is about 2 micrometers (μm) by 2 μm, active area 102 is about 4 μm by 2 μm, gates 3 and 103 are about 40 nanometers (nm) in width (in the left-to-right direction of FIG. 1) where they extend over active areas 1 and 102, and contact areas 4, 104 are each about 90 nm by 90 nm. A dual-stress liner is also provided. The dual-stress liner applies compressive stress to PFET 101, and the compressive stress portion of the dual-stress liner has boundaries that extend along the x direction that are identical to the boundaries 110 and 11 of N-well 2. The compressive stress portion of the dual-stress liner also has boundaries that extend along the y direction that are identical to boundaries 112 and 113 of N-well 2. The remainder of the dual-stress liner applies tensile stress to the region that includes NFET 100.

Because conventional dual-stress liners have boundaries that depend on the shape and size of the N-well, there is typically a first distance in the y direction between a PFET channel and one boundary of the compressive portion of the dual-stress liner that is different from a second distance in the y direction between the channel and the opposing boundary of the compressive portion. For example, in FIG. 1, distance d1 is 10 μm and distance d2, which is different, is only 2 μm. Moreover, because the compressive liner boundaries are defined by the N-well boundaries, the values of d1 and d2 can be different for different PFETs in the same semiconductor device. This means that the amount of y-direction compressive stress applied to one PFET in a semiconductor device may be different than the amount of y-direction compressive stress applied to another PFET in the semiconductor device, depending upon its location within the N-well. For instance, a conventional CMOS device may have an group of NFETs and PFETs, where an N-well encompasses the PFETs. Depending upon the location of any given PFET that PFET may experience less compressive stress along the y direction than another PFET in the group. This is because one PFET may be closer to a border of the N-well (and thus closer to the border of the compressive portion of the compressive liner) than another of the PFETs. The result of this is that the PFET will have different performance characteristics. This performance difference is usually undesirable.

The same problem often occurs in another conventional configuration, shown in FIG. 2 (which is also not to scale). Here, NFET 100 and PFET 101 share the same gate 3. In this case, PFET 101 has a first distance d3 in the y direction between the channel and a first boundary 112 of the compressive portion of the dual-stress liner that is different from a second distance d4 in the y direction between the channel and a second opposing boundary 113 of the compressive portion. Again, this results in differing performance characteristics between PFETs in the device, where many of the PFETs that have excessive compressive stress along the y direction have relatively low performance.

### SUMMARY

As previously mentioned, performance improvements have been limited using traditional dual-stress liner configurations. A major reason for this is that such traditional configurations apply excess compressive stress to PFET channels in the y direction. However, compressive stress applied to PFET channels in the y direction degrades PFET mobility. In addition, traditional dual-stress liners provide inconsistent and non-matched performance among PFETs.

For instance, large-scale integration (LSI) circuits use matching PFETs in analog circuits and/or memory sense amplifiers. Matching PFETs are a pair of PFETs having characteristics that are well-matched. In general, gate length, channel width, contact size, and contact-gate distance should be designed equally within a matched pair. However, the particular sizes and shapes of the N-well and P-well are designed on a case-by-case basis as they do not directly affect PFET characteristics. When using a dual-stress liner in such a circuit, PFET characteristics are strongly affected by the stress liners. Thus, aspects of the present invention are directed to providing a way of controlling what the affect is by a stress liner on a given PFET by controlling the distance between the channel (or other PFET feature) and the stress liner edge to be the same between the matched PFETs, regardless of the shapes and sizes of the N-well and P-well. Aspects of the present invention therefore may be useful for matching PFETs.

In addition, aspects of the present invention are directed to providing dual-stress liner configurations that achieve better and/or more consistent PFET performance than traditional dual-stress liner configurations.

Further aspects of the present invention are directed to providing dual-stress liner configurations that apply less compressive stress to PFETs in the y direction than in the x direction. In such configurations, the compressive portion of the dual-stress liner over a PFET may be substantially shorter in the y direction than in the x direction.

Still further aspects of the present invention are directed to providing dual-stress liner configurations that provide less compressive stress to PFETs in the y direction than traditional dual-stress liner configurations.

Still further aspects of the present invention are directed to providing dual-stress liner configurations wherein the compressive liner portion extends from a PFET channel by a predetermined distance. The predetermined distance may be, for example, as short as the minimum design rule allows for a given semiconductor device, or in any event shorter than the distance from the PFET channel to the edge of the PFET active area in the y direction. Alternatively, the predetermined distance may be slightly larger than the distance from the PFET channel to the edge of the PFET active area in the y direction.

These and other aspects of the invention will be apparent upon consideration of the following detailed description of illustrative embodiments.

### BRIEF DESCRIPTION OF THE DRAWINGS

A more complete understanding of the present invention and the advantages thereof may be acquired by referring to the following description in consideration of the accompanying drawings, in which like reference numbers indicate like features, and wherein:

FIGS. 1 and 2 are plan views of conventional CMOS devices with dual-stress liners.

FIGS. 3 and 4 are plan views of CMOS devices with dual-stress liners in accordance with at least one aspect of the present invention.

FIGS. 5, 6, 8, 10, 12, and 14 are cross-sectional views along cross section A-A′ of FIG. 3, illustrating steps that may be taken to fabricate a dual-stress liner.

FIGS. 7, 9, 11, and 13 are cross-sectional views along cross section B-B′ of FIG. 4, illustrating steps that may be taken to fabricate a dual-stress liner.

FIGS. 15-17 show experimental results obtained in connection with various configurations of compressive stress liners.

FIG. 18 is a plan view of a CMOS device with a dual-stress liner in accordance with at least one aspect of the present invention.

FIG. 19 is a cross-sectional view along cross section C-C′ of FIG. 18.

FIG. 20 is a cross-sectional view along cross section D-D′ of FIG. 18.

FIG. 21 is a cross-sectional view along cross section E-E′ of FIG. 18.

FIG. 22 is a plan view of an illustrative N-well containing a plurality of PFETs.

FIGS. 23 and 24 are plan views of CMOS devices with dual-stress liners in accordance with at least one aspect of the present invention.

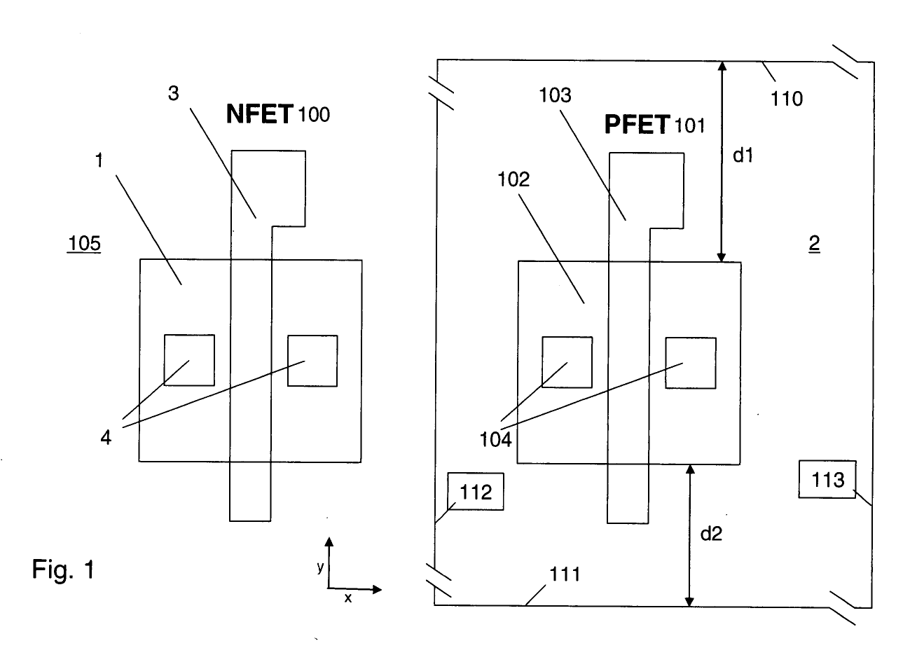

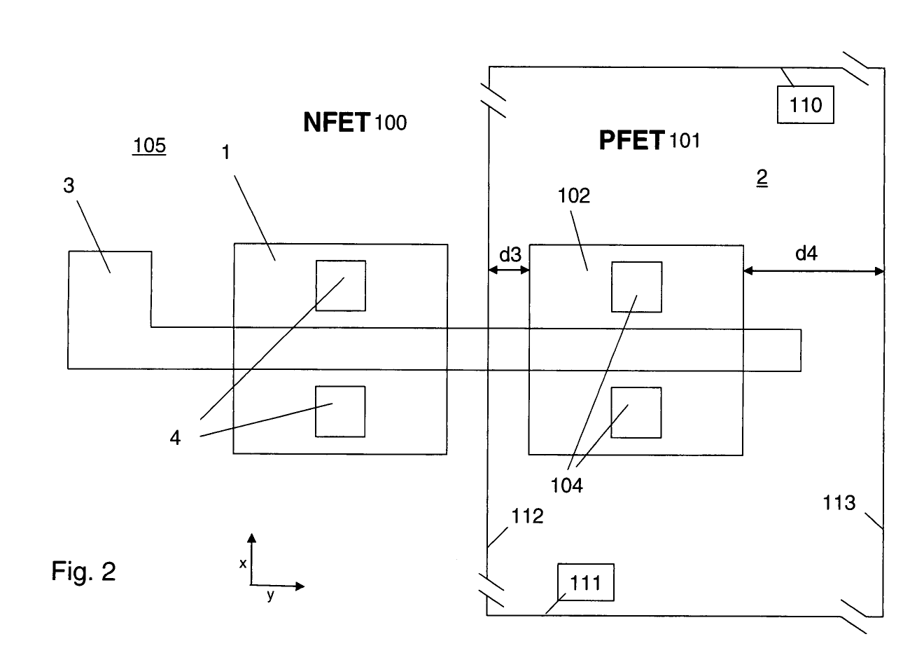

### DETAILED DESCRIPTION OF ILLUSTRATIVE EMBODIMENTS

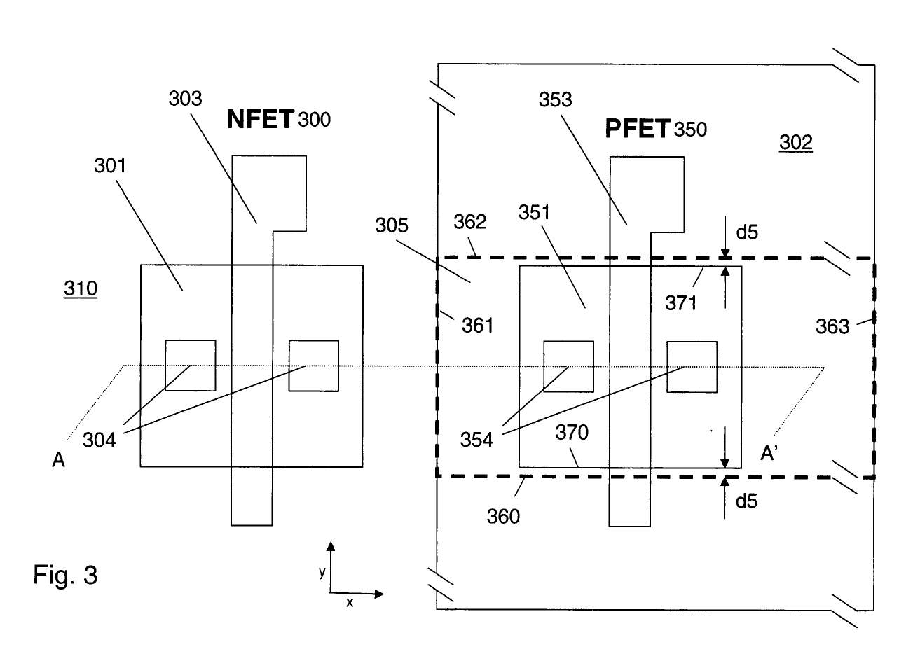

Referring to FIG. 3 (which is not to scale), an illustrative semiconductor device is shown that includes an NFET 300 and a PFET 350 disposed near NFET 300. NFET 300 may be a conventional NFET with an active region 301 and a pair of contacts 304 disposed on opposing sides of a gate 303. NFET 300 may be disposed in a P-well 310. PFET 350 may be a conventional PFET with an active region 351, and a pair of contacts 354 on opposing sides of a gate 353. PFET 350 may be disposed in an N-well 302. A dual-stress liner has a compressive portion 305 over at least a portion of PFET 350 and a tensile portion (the remainder of the dual-stress liner) over at least a portion of NFET 300. It should be N-well 302 may contain not only PFET 350, but also one or more other PFETs. Each of these PFETs may have their own individual compressive layers or they may share compressive layer 305 as one continuous layer.

A boundary 360, 361, 362, 363 exists between the tensile portion and compressive portion 305 of the dual-stress liner. Boundaries 360 and 362 extend along the x direction, and boundaries 361 and 363 extend along the y direction. In this embodiment, boundaries 361 and 363 are each approximately co-located with, or disposed over, a respective boundary along the x direction of N-well 302, and boundaries 360 and 362 are each located a predetermined distance d5 from, and outside of, an edge 370 and 371 of active area 351. In addition, boundaries 360 and 362 are located inside of N-well 302. This means that both the compressive liner and a portion of the tensile liner are disposed over N-well 302. In this particular embodiment, distance d5 is 100 nm. However, d5 may be of any distance that is fixed for a plurality of PFETs on the same semiconductor device. For example, d5 may be the smallest distance that is possible using the manufacturing techniques implemented for the semiconductor device (e.g., as defined by the minimum design rule).

By defining certain compressive region boundaries in accordance with active region 351 instead of N-well 302, the amount of y direction compressive stress on each PFET channel of a semiconductor device may not only be reduced, but may also be uniform across the PFETs. Where the same distance d5 is used for a group of PFETs on a semiconductor device, each of the PFETs may have more uniform and/or predictable performance characteristics. For example, one or more of the other PFETs in N-well 302 may be a matching PFET with respect to PFET 350. In other words, those one or more matching PFETs would have the same size and/or shape compressive layer as PFET 350, allowing them to have a set of performance characteristics in common with PFET 350. These other PFETs may be matched to have the same performance characteristics even though they may be closer or further in the y direction from a boundary of N-well 302. This is because the size of compressive layer 305 in the y direction may be configured independent of the location of each PFET within N-well 302.

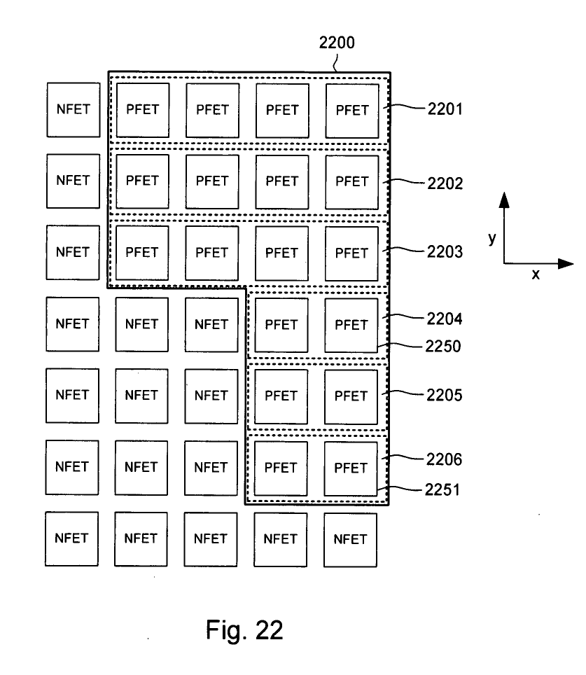

For example, referring to FIG. 22, an illustrative N-well 2200 is shown containing a plurality of PFETs including PFET 2250 and 2251. In this particular embodiment, the PFETs are arranged in rows, and each row has its own separate compressive layer 2201, 2202, 2203, 2204, 2205, 2206 (their boundaries being indicated in FIG. 22 by broken lines) extending longitudinally in the x direction. Each compressive layer 2201-2206 has the same width in the y direction. Thus, the compression in the y direction on each PFET in N-well 2200 is the same. Although the distance of the compressive layer in the x direction may be different for each PFET in a given row, it has been found that distances in the x direction beyond ten times the thickness of the compressive layer do not affect the amount of compression in the x direction by very much; the x direction compression becomes saturated at larger distances. Thus, each of the PFETs in a given row would be expected to be subject to similar x direction compressive forces. Alternatively, to more precisely control the x direction compression, each PFET may have its own dedicated separate compressive layer, instead of sharing a compressive layer with other PFETs in the row. As previously discussed, conventional compressive layers would extend as one continuous layer throughout the extent of the N-well, resulting in differing amounts of compression in the y direction for different PFETs in the N-well. Thus, by separating compressive layers into rows or even dedicated layers for each PFET, y direction compression may be easily controlled.

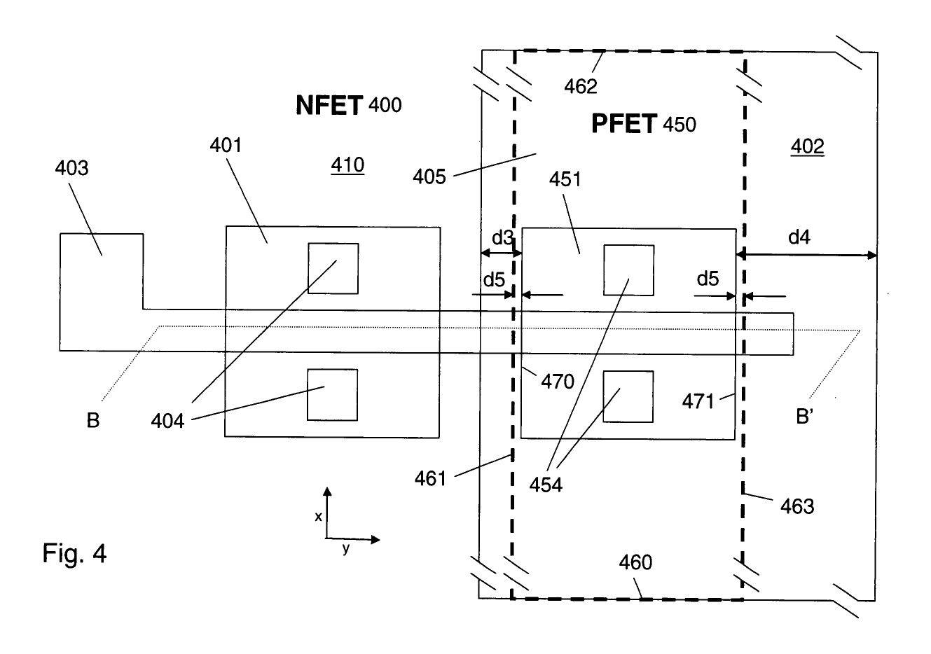

FIG. 4 shows another illustrative configuration where an NFET 400 and a PFET 450 share a same gate 403. NFET 400 has an active area 401 and contacts 404, and PFET 450 has an active area 451 and contacts 454. In this embodiment, a boundary 460, 461, 462, 463 exists between a tensile portion and a compressive portion 405 of the dual-stress liner. Boundaries 461 and 463 extend along the x direction, and boundaries 460 and 462 extend along the y direction. In this embodiment, boundaries 460 and 462 are each approximately co-located with, or disposed over, a respective boundary along the x direction of N-well 402, and boundaries 461 and 463 are each located a predetermined distance d5 from, and outside of, a respective edge 470 and 471 of active area 451. In addition, boundaries 461 and 463 are located inside of N-well 402. This means that both the compressive liner and a portion of the tensile liner are disposed over N-well 402.

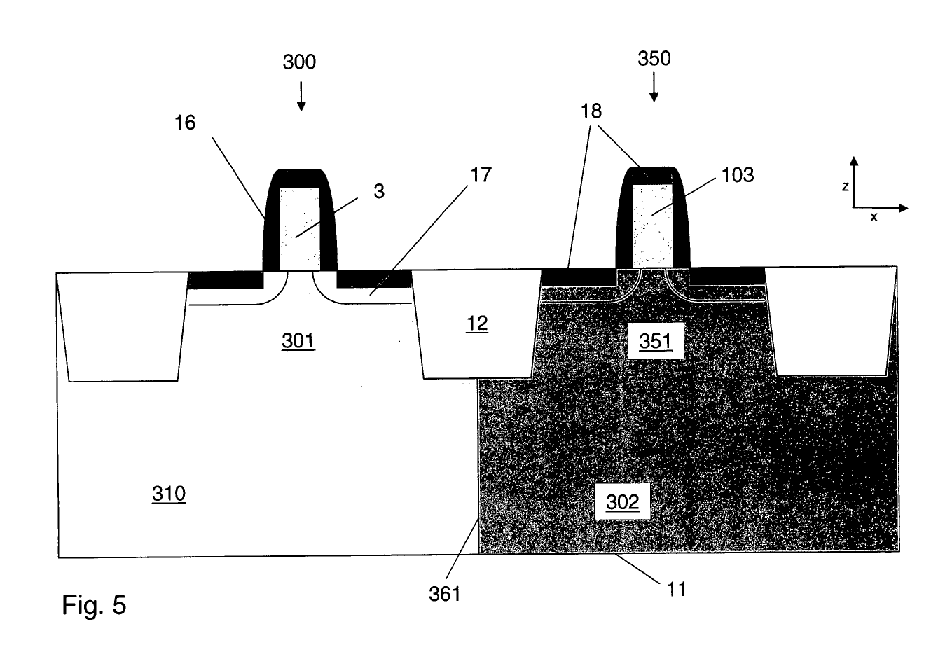

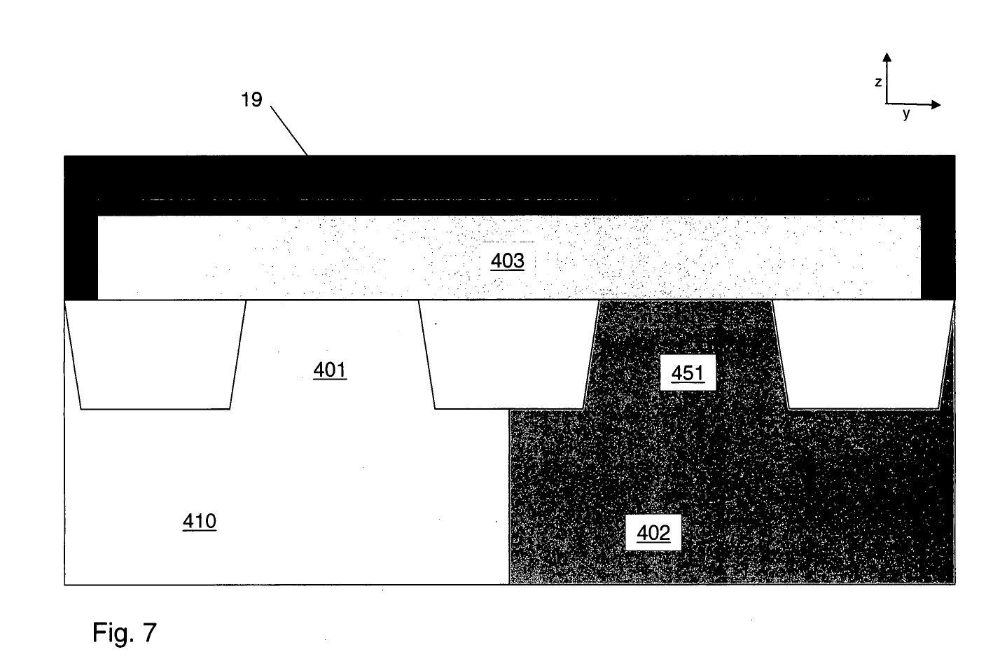

Illustrative methods for manufacturing devices in accordance with aspects of the invention are now described with reference to FIGS. 5-14. FIGS. 5, 6, 8, 10, 12, and 14 show the manufacturing of the device in FIG. 3 with a cross-sectional view along A-A′ , and FIGS. 7, 9, 11, and 13 show the manufacturing of the device in FIG. 4 with a cross-sectional view along B-B′ .

Referring to FIG. 5, a shallow trench isolation (STI) layer 12 is formed in a silicon substrate 11. STI layer 12 may have a depth of, for example, about 100 nm. P-well 310 and N-well 302 are formed in pre-determined areas so that NFET 300 and PFET 350, respectively, may be formed. Gates 3 and 103 are formed from polysilicon. Each gate 3, 103 may have dimensions of, for example about 100 nm in height and about 40 nm in width. Also, a gate oxide layer (not shown), which may be about 1 nm in thickness, is formed between gates 3 and 103 and silicon substrate 11. Sidewall spacers 16 are added to the sides of gates 3 and 103, which may each have a width of, for example, about 20 nm. A source/drain diffusion region 17 is also formed, and a silicide layer 18 is formed in the exposed active area and on top of gates 3 and 103 using a conventional silicide process. Silicide layer 18 may have a thickness of, for example, about 30 nm, and may be made of, for example, CoSi or NiSi.

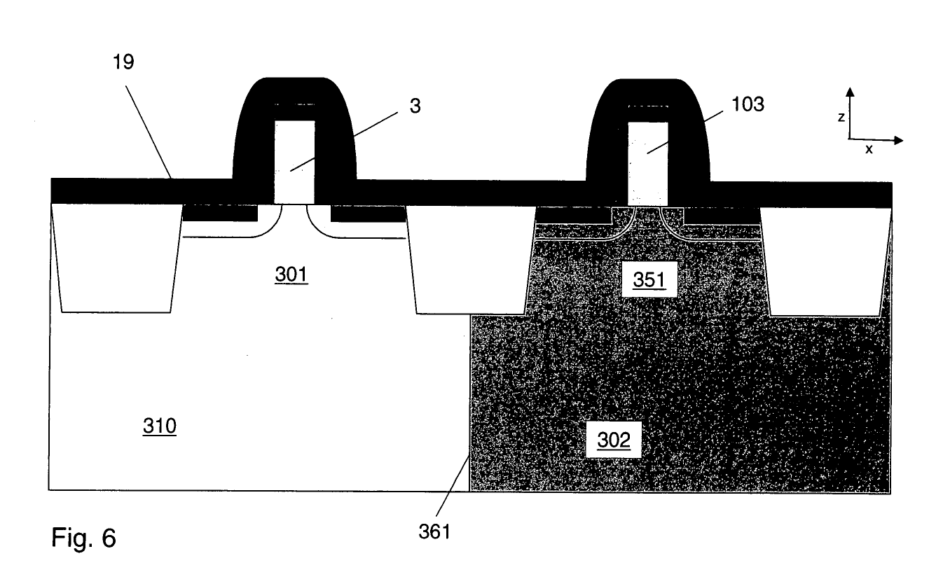

Referring to FIG. 6, after formation of silicide layer 18, a tensile SiN film 19 is deposited over the entire surface. Tensile film 19 may have a thickness of, for example, about 50 nm. This same step is also shown in FIG. 7 for the device of FIG. 4.

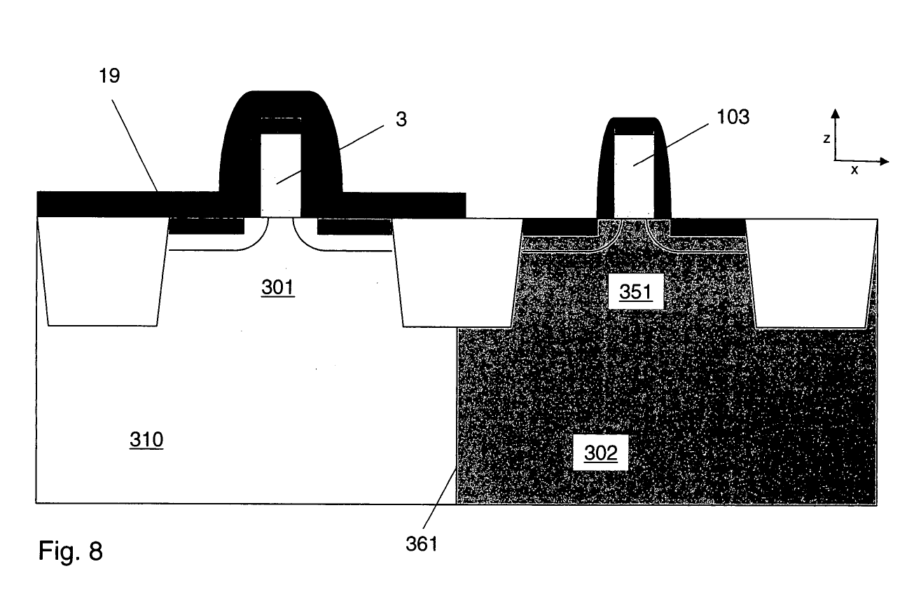

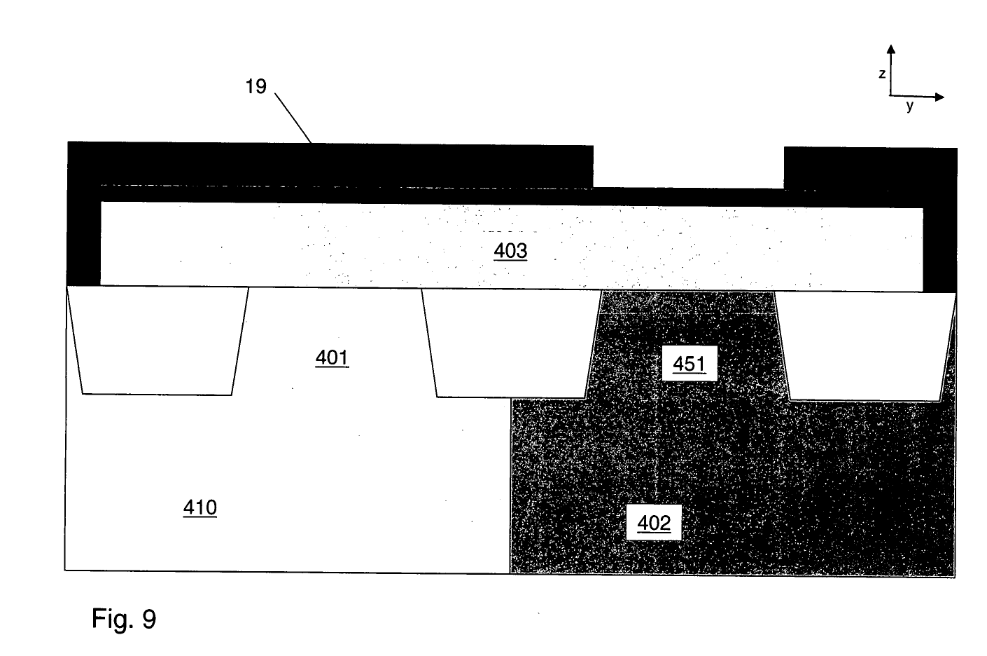

Referring to FIG. 8, tensile film 19 is then selectively removed locally from the PFET area using conventional lithography and reactive ion etching (RIE) techniques. The result is that tensile film 19 extends up to P-well boundary 361. This same step is also shown in FIG. 9 for the device of FIG. 4, where tensile film 19 is removed such that the remaining tensile film 19 extends up to a predetermined distance from the edge of active area 451.

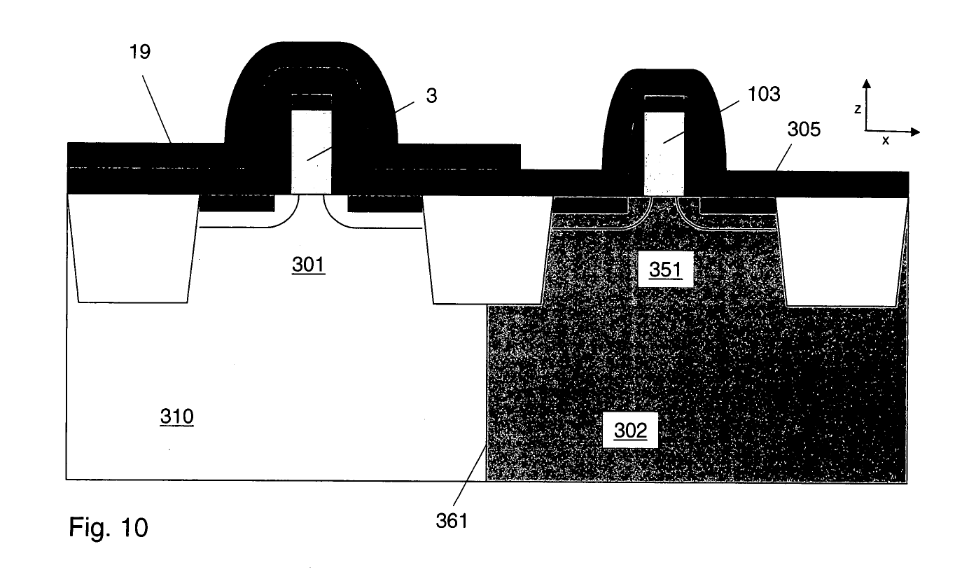

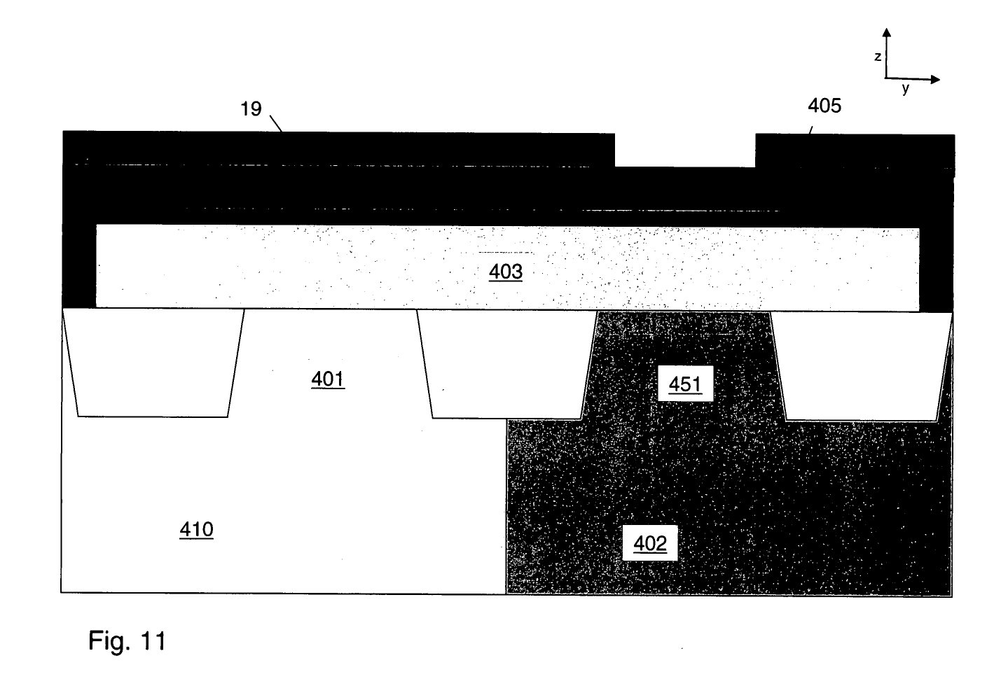

Referring to FIG. 10, compressive SiN film 305 is deposited over the entire surface of the device. Compressive film 305 may have a thickness of, for example, about 50 nm. This same step is also shown in FIG. 11 for the device of FIG. 4.

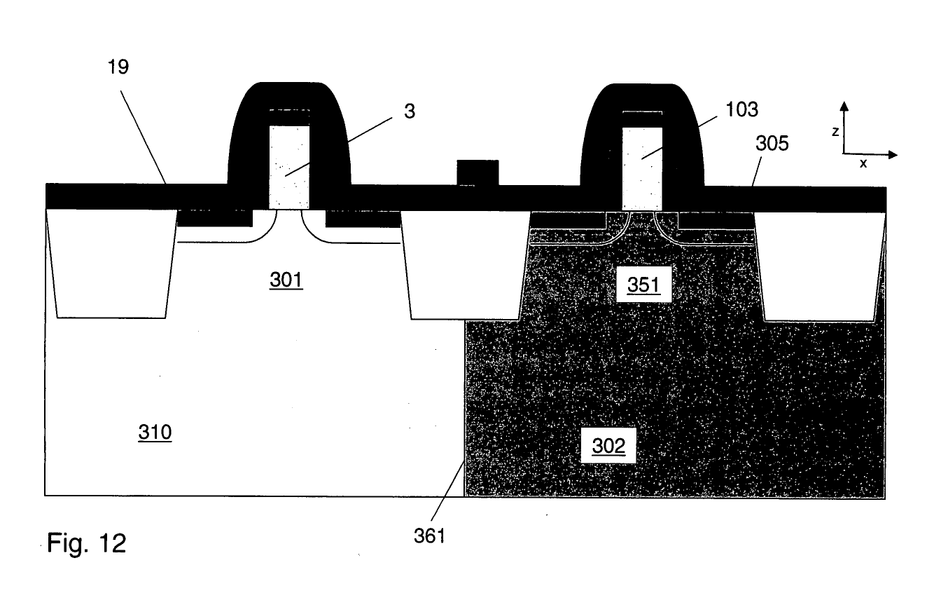

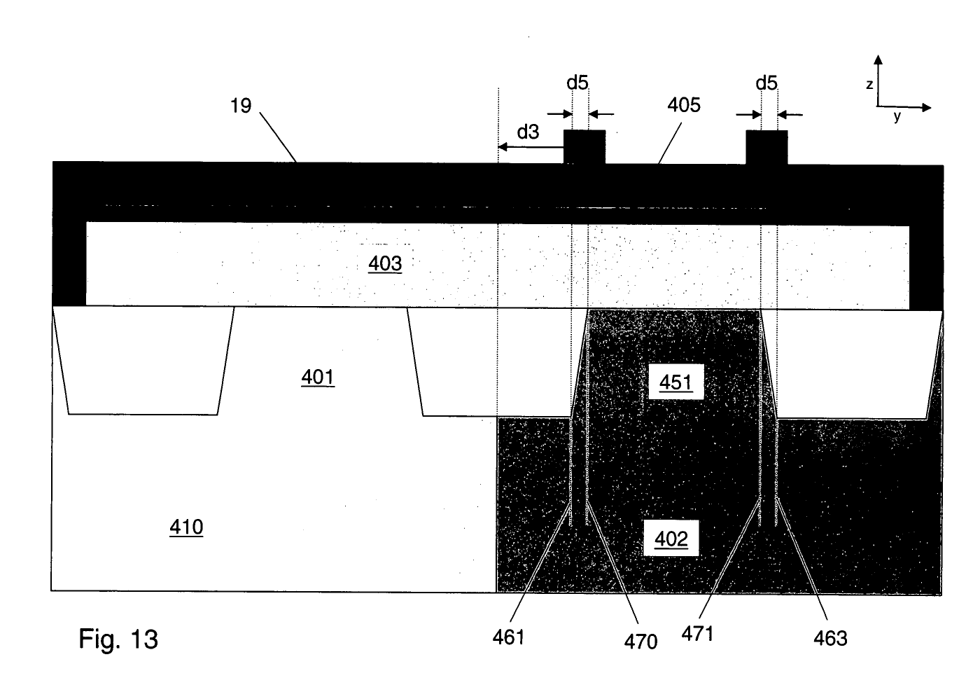

Referring to FIG. 12, compressive film 305 is then selectively removed locally from the NFET area using conventional lithography and RIE techniques. The result is that SiN film 305 extends up to P-well boundary 361. This same step is also shown in FIG. 13 for the device of FIG. 4, where compressive film 405 is removed such that the remaining compressive film 405 extends up to tensile film 19.

Referring to FIG. 14, an inter-level dielectric (ILD) film 21 is deposited over films 19 and 305. ILD film 21 may be, for example, about 400 nm thick. Then, contact holes 22 are opened and filled with contact metal.

It should be noted that some of the figures (e.g., FIG. 13) show tensile film 19 and compressive film 405 slightly overlapping. Conventionally, the boundary between compressive and tensile layers forms a gap. This gap has been known to cause problems with unexpected etching. Thus, to reduce this problem, an overlap may be provided as shown in the figures. Where an overlap exists, the boundary between the compressive and tensile portions of a dual-stress liner may be considered to be, for example, the middle of the overlap.

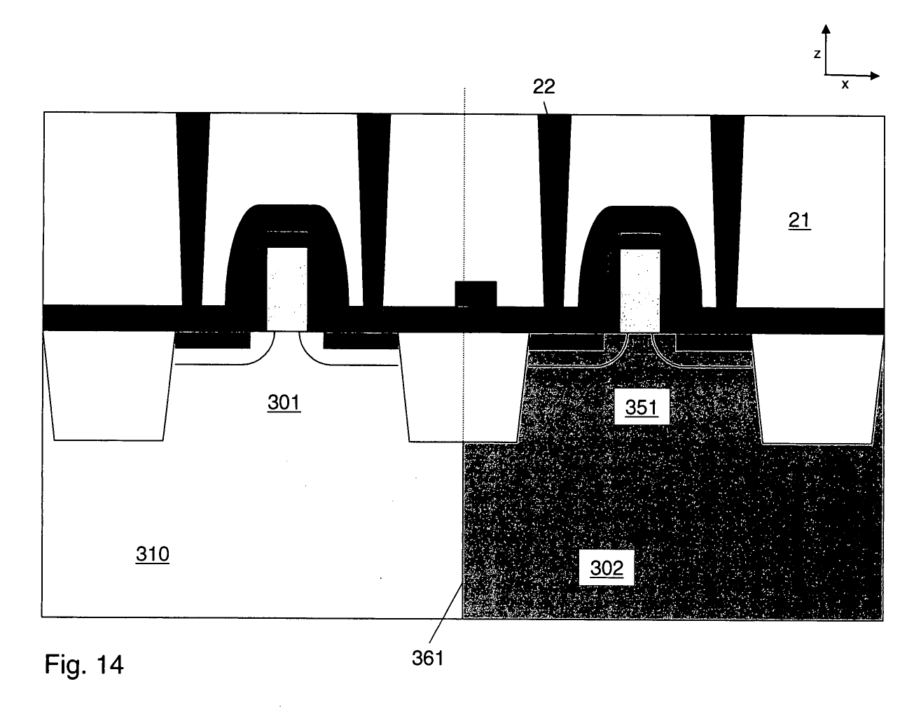

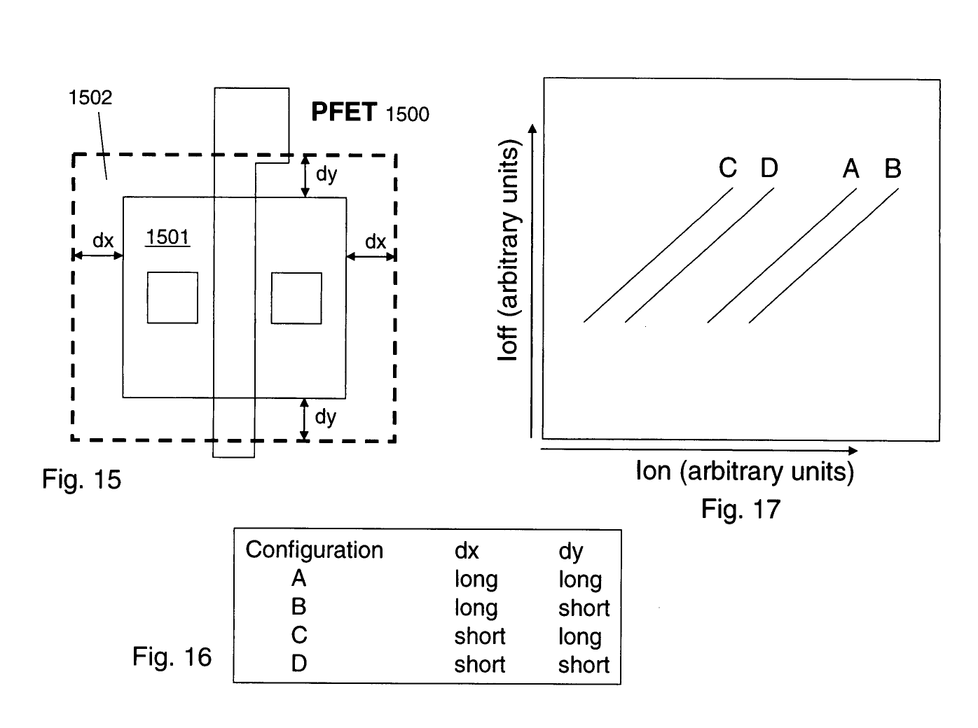

FIGS. 15-17 show illustrative experimental results showing the effects of various distances between the edge of the compressive film and the edge of the active area along the x and y directions. Referring to FIG. 15, a PFET 1500 is shown having an active area 1501 and an overlying compressive SiN film 1502. A tensile SiN film (not shown) surrounds compressive SiN film 1502. The edges of compressive SiN film 1502 are located outside active area 1501 by a predetermined distance dx in both x directions and a predetermined distance dy in both y directions. Distances dx and dy may be the same amount or different amounts. Also, although distance dx is shown to be identical on both the left and right sides of FIG. 15, they may be different. Likewise, although distance dy is shown to be identical on both the top and bottom sides of FIG. 15, they may be different.

Referring to FIG. 16, are shown for four configurations: A, B, C, and D, which represent different combinations of short and long dx and dy. Configuration “A” has a long dx and a long dy. Configuration “B” has a long dx and a short dy. Configuration “C” has a short dx and a long dy. Configuration “D” has a short dx and a short dy. A “short” dx or dy in this example refers to the minimum design rule distance, which in this example is no more than about 100 nm. Also, in this example, a “long” dx or dy refers to a distance at least ten times longer than the thickness of the compressive film 1502 (for example, at least about 1 μm). It has been found that the amount of compression in the x direction becomes saturated as distances are increased beyond about ten times the compressive film thickness in the x direction. However, any distances for dx and dy may be used.

Referring to FIG. 17, which shows Ion versus Ioff characteristics for each configuration, it is apparent that configuration “B” provides the best PFET performance (where dx is long and dy is short). This is because the large dx causes compression to be large along the x direction and the small dy causes compression to be relatively small along the y direction. Due to the properties of a PFET as discussed previously, this is a desirable combination. In contrast, configuration “C” provides the worst PFET performance, where dx is short and dy is long, causing compressive forces to be large along the y direction and small along the x direction. This is an undesirable combination because it severely reduces PFET performance.

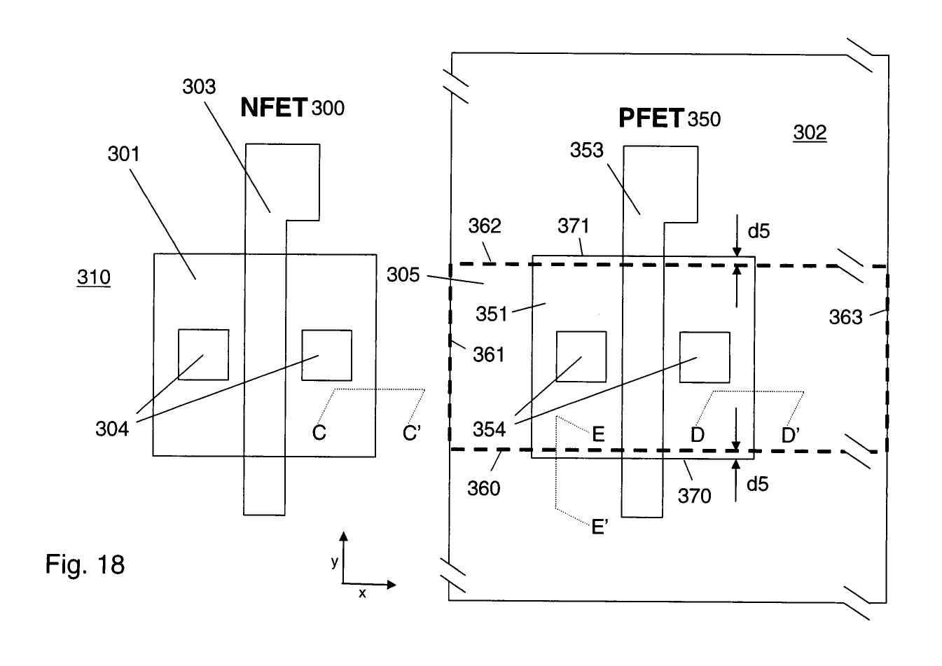

FIG. 18 shows a variation on the embodiment of FIG. 3, except that distance d5 is negative. In other words, at least some of the boundaries of compressive liner 305 are located within the bounds of active area 351. For example, distance d5 may be −50 nm. In other words, active area 351 and the tensile liner overlap by about 50 nm. By implementing a negative d5, this reduces still further the compressive stress applied in the y direction, which improves the performance of the PFET even more. The embodiment of FIG. 4 may likewise implement a negative distance d5.

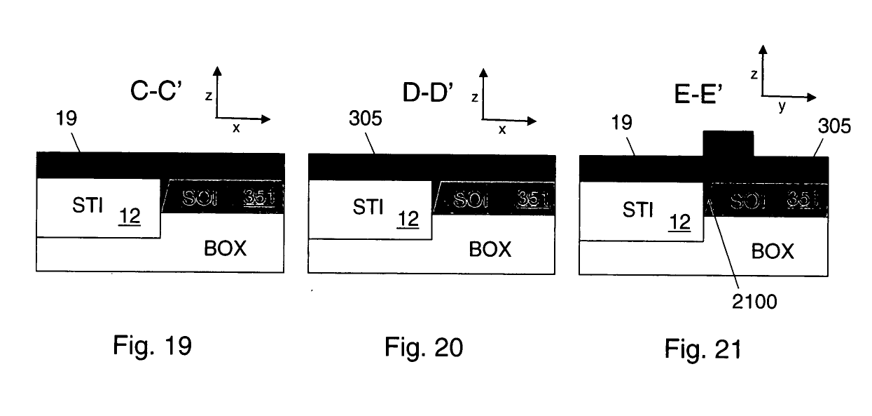

The various aspects discussed thus far may be used in both bulk and silicon-on-insulator (SOI) devices. In an SOI device, an SOI active area is disposed over a buried oxide (BOX) layer, and an STI trench is disposed next to the active area. FIGS. 19-21 show an example of how the configuration of FIG. 18 may be formed in such an SOI device. FIG. 19 shows a view along cross section C-C′ of FIG. 18; FIG. 20 shows a view along cross section D-D′ of FIG. 18; and FIG. 21 shows a view along cross section E-E′ of FIG. 18. As can be seen, a conventional STI process produces a downward-facing divot at the interface between STI 12 and SOI active layer 351. This divot is filled with either tensile liner 19 (as in FIGS. 19 and 21) or compressive liner 305 (as in FIG. 20). Where d5 is negative, as in FIGS. 18 and 21, the divot is filled with tensile liner 19 such that tensile liner 19 actually touches an outer edge 2100 of active area 351 while compressive liner 305 is disposed over active area 351.

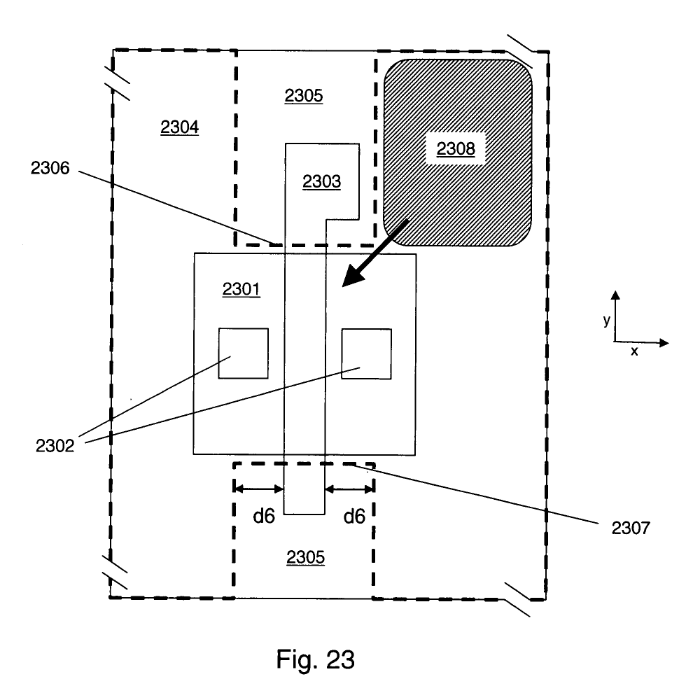

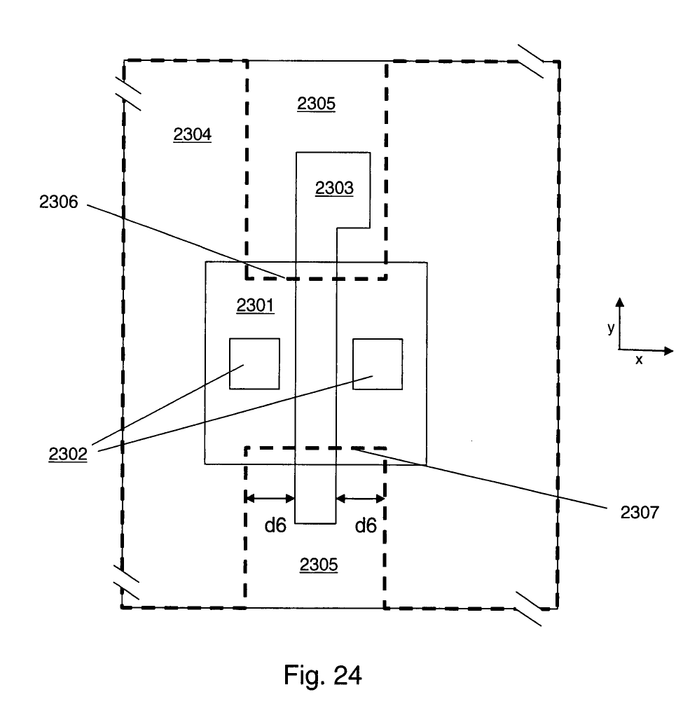

FIGS. 23 and 24 illustrate additional examples of embodiments where performance is significantly enhanced by the shapes and relative sizes of the compressive and tensile portions of the dual-stress liner. In these embodiments, a PFET has an active area 2301 with contacts 2302 on opposing sides of a conductive gate 2303. Disposed over the PFET is a dual-stress liner including a compressive portion 2304 and a tensile portion 2305. As can be seen, compressive portion 2304 has boundaries that form approximately in the shape of a capital “H.” A distance d6 between gate 2303 outside of active area 2301 and compressive portion 2304 may be adjusted as desired, such as between zero to approximately 1 μm. For example, distance d6 may be approximately 0.2 μm. As can also be seen, boundaries 2306 and 2307 may either extend over active area 2301 (FIG. 24) or not (FIG. 23).

A corner region 2308 is differentiated in FIG. 23 for illustration purposes only; it is not actually a separate region from the remainder of compressive portion 2304. Corner region 2308, because of its location relative to active area 2301, provides affects active area 2301 in both the x and y directions.. However, the effect of the x-direction compression is greater than the effect of the y-direction tension. Accordingly, the compression applied by comer region 2308 may be even more beneficial as compared with the embodiment in, for example, FIG. 3. This is why the “H” shape may be an advantageous shape for the boundary of compressive portion 2304.

Thus, improved ways of controlling the boundaries between the compressive and tensile portions of a dual-stress liner have been described. By controlling the boundaries appropriately relative to the PFET as opposed to being dictated by the N-well boundaries, the opportunity to improve and/or match PFET performance may be provided.

What is claimed is:

1. A semiconductor device, comprising:
a substrate;
a PFET disposed in the substrate and having an active area enclosed by a trench isolation layer, wherein the active area has a first pair of opposing boundaries extending along an x direction and a second pair of opposing boundaries extending along a y direction;
a tensile layer disposed over the trench isolation layer and extending in the y direction across at least one of the first pair of boundaries such that the tensile layer is also disposed over the active area; and
a compressive layer disposed over the active area and extending in the x direction across at least one of the second pair of boundaries such that the compressive layer is also disposed over the trench isolation layer.

2. The semiconductor device of claim 1, wherein the semiconductor device further includes an N-well disposed in a portion of the substrate, wherein the N-well contains the PFET, and wherein the compressive layer extends in the x direction to a boundary of the N-well.

3. The semiconductor device of claim 1, wherein the compressive layer has a boundary at least partially disposed over the active area.

4. The semiconductor device of claim 1, wherein the compressive layer has two opposing boundaries each at least partially disposed over the active area.

5. The semiconductor device of claim 1, wherein the tensile layer touches an edge of the active area.

6. The semiconductor device of claim 1, wherein the PFET is disposed in an N-well, and wherein the compressive layer extends in the x direction to a boundary of the N-well.

7. A semiconductor device, comprising:
a substrate;
an N-well disposed in a portion of the substrate;
a first PFET having a first channel disposed in the N-well at a first distance in a y direction from a first boundary of the N-well;
a second PFET having a second channel disposed in the N-well at a second distance in the y direction from the first boundary of the N-well, wherein the second distance is different from the first distance;
a first compressive layer disposed over the first PFET and having a boundary at a third distance in the y direction from the first channel; and
a second compressive layer disposed over the second PFET and having a boundary at the third distance in the y direction from the second channel.

8. The semiconductor device of claim 7, further including a tensile layer disposed over the N-well.

9. The semiconductor device of claim 7, wherein the first and second compressive layers are a single continuous compressive layer.

10. The semiconductor device of claim 7, wherein the first and second compressive layers each extend in an x direction to a second boundary of the N-well.

11. The semiconductor device of claim 7, wherein the boundary of the first compressive layer is disposed over an active layer of the first PFET, and wherein the boundary of the second compressive layer is disposed over an active layer of the second PFET.

12. The semiconductor device of claim 7, wherein the boundary of the first compressive layer is within a minimum design rule distance of a boundary of an active layer of the first PFET, and wherein the boundary of the second compressive layer is within the minimum design rule distance of a boundary of an active layer of the second PFET.

13. The semiconductor device of claim 7, wherein the boundary of the first compressive layer is no more than 100 nanometers from a boundary of a first active layer of the first PFET, wherein the boundary of the second compressive layer is no more than 100 nanometers from a boundary of a second active layer of the second PFET, wherein the first compressive layer extends in an x direction from the first active layer by at least 1 micrometer, and wherein the second compressive layer extends in the x direction from the second active layer by at least 1 micrometer.

14. The semiconductor device of claim 7, wherein the first and second PFETs have a same set of performance characteristics as each other.

15. A semiconductor device, comprising:
a substrate;
an N-well disposed in a first portion of the substrate;
a PFET disposed in the N-well;
a compressive layer disposed over the PFET; and
a tensile layer disposed over the N-well.

16. The semiconductor device of claim 15, wherein the tensile layer extends to a second portion of the substrate outside of the N-well.

17. The semiconductor device of claim 15, wherein the PFET has an active area, and wherein the tensile layer is disposed over the active area.

18. The semiconductor device of claim 15, wherein the compressive layer is longer in an x direction than in a y direction.

19. The semiconductor device of claim 15, wherein the PFET has an active area, and wherein the compressive layer extends in a y direction over a first boundary of the active area by no more than 100 nanometers.

20. The semiconductor device of claim 19, wherein the compressive layer extends in an x direction over a second boundary of the active area by at least 1 micrometer.
